(19) United States
(12) Patent Application Publication
(10) Pub. No.: US 2013/0330206 A1
(43) Pub. Date: Dec. 12, 2013

(54) INTEGRATED FUEL PUMP AND CONTROL

(71) Applicant: Jeremy J. Walters, San Diego, CA (US)

(72) Inventor: Jeremy J. Walters, San Diego, CA (US)

(73) Assignee: HAMILTON SUNDSTRAND CORPORATION, Windsor Locsk, CT (US)

(21) Appl. No.: 13/490,573

(22) Filed: Jun. 7, 2012

(51) Int. Cl. F04B 49/06; H05K 13/04

(52) U.S. Cl. 417/44.1; 29/592.1; 29/825

(57) ABSTRACT

An integrated fuel pump and control system includes a pump assembly with an inlet and an outlet; a motor connected to the pump assembly to provide power to the pump assembly; a controller to regulate the speed of the motor; and a housing to contain the pump assembly, the motor and the controller.

### BACKGROUND

This invention relates generally to pumping systems, and specifically to fuel pumping and control systems.

Gas turbine and jet engines are controlled by an analog or digital computer that receives inputs from the vehicle and from the engine and produces control signals that are sent to a fuel controlling device. In some cases, the fuel controlling device is a variable speed pump with flow controlled by the speed of the pump. The speed of the pump can be controlled by a computer.

### SUMMARY

An integrated fuel pump and control system includes a pump assembly with an inlet and an outlet; a motor connected to the pump assembly to provide power to the pump assembly; a controller to regulate the speed of the motor; and a housing to contain the pump assembly, the motor and the controller.

A method of forming an integrated fuel pump and control system includes providing a housing with a wet portion and a dry portion; placing a pump assembly in the wet portion for transferring fuel through an outlet; placing a motor in the wet portion for providing power to the pump assembly; and placing a controller in the dry portion for regulating the motor.

### BRIEF DESCRIPTION OF THE DRAWINGS

FIG. 1A shows a perspective view of a fuel pumping and control system.

FIG. 1B shows a plan view of the fuel pumping and control system of FIG. 1A.

FIG. 2 shows block diagram of the inside of the fuel pump and control system of FIGS. 1A-1B.

### DETAILED DESCRIPTION

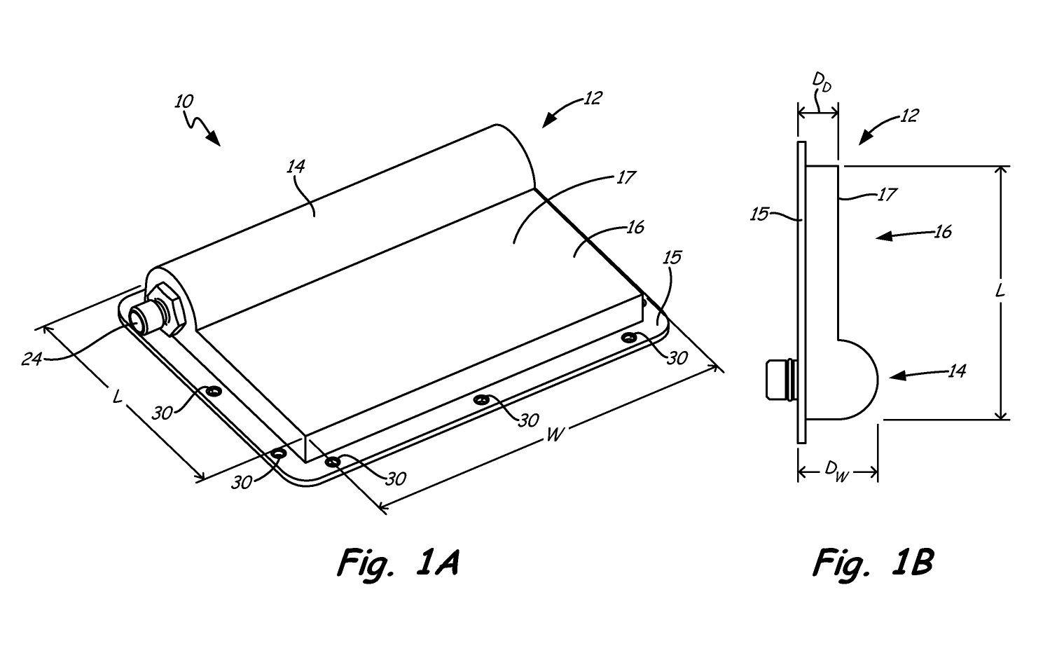

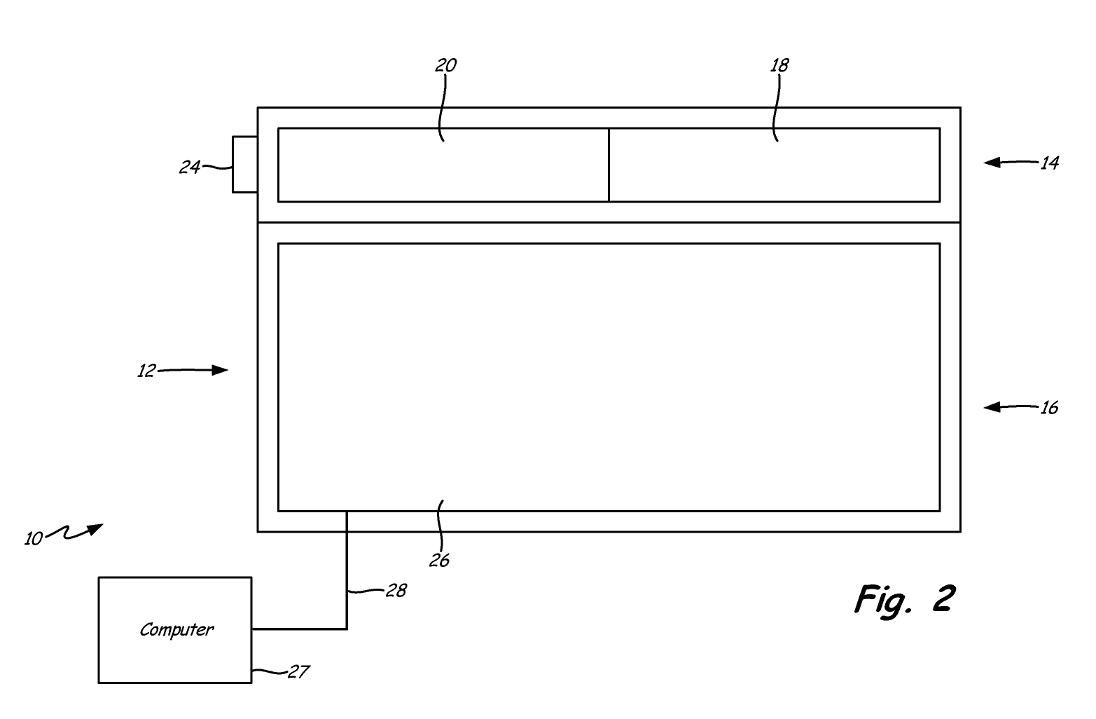

FIG. 1A shows a perspective view of a fuel pumping and control system 10. FIG. 1B shows a side view of fuel pumping and control system 10. FIG. 2 shows a block diagram of showing the inside components of fuel pump and control system 10. In an embodiment, fuel pumping and control system 10 includes housing 12 with wet compartment 14 and dry compartment 16, motor 18, pump assembly 20, fuel inlet 22 connected to a fuel tank (not shown), fuel outlet 24 connected to a fuel manifold of an engine (not shown), controller 26 and computer 27. In an non-limiting example, fuel pumping and control system 10 can be mounted directly onto a fuel tank (not shown) using bolts or other fasteners that are received within holes 30, but other methods of attachment depending on system requirements may also be used.

Housing 12 is one integral part with a generally cylindrical portion for wet compartment 14 that is coupled to a generally rectangular portion for a dry compartment 16. The housing 12 generally has a flat base 15 and cover portion 17 which extends in the depth dimension to hold components in wet compartment 14 and dry compartment 16. Wet compartment 14 and dry compartment 16 are separate sealed chambers so that fuel cannot leak from wet compartment 14 and contact electronics in dry compartment 16. Housing 12 can include sealed feed-through holes between wet compartment 14 and dry compartment 16 to send electricity and signals between controller 26 and motor 18. Housing 12 can be made of aluminum (including alloys), titanium (including alloys), other metals, or other materials depending on system requirements. Housing dimensions shown are width W, length L, depth of wet compartment D_{W} and depth of dry compartment D_{D}. In the example shown, dimensions are width W of about 6 inches (about 15.24 cm), length L of about 4 inches (about 10.16 cm), depth of wet compartment D_{W} of is about 1.875 inches (about 4.7625 cm) and depth of dry compartment D_{D} of about 0.625 inches (about 1.5875 cm). Though not shown in FIGS. 1A-2, housing 12 can include a feed-through hole to bring electricity into housing to power controller 26 and motor 18.

Pump assembly 20 can be a cylindrical pump, such as, for example, a rotary pump, a piston pump, a vane pump or another type of pump that is located in wet compartment 14. Pump assembly 20 transports fuel received from fuel inlet 22 through fuel outlet 24 when rotating. Motor 18 can be a brushless motor or any other type of electric motor that is able to power pump assembly 20 and is able to fit within wet compartment 14 of housing 12. Controller 26 can comprise a Full Authority Digital Electronic Control (“FADEC”) and motor drive circuitry.

Controller 26 can be connected to computer 27 through wires 28 (through a feed-through in housing 12) or wirelessly to receive signals for controlling fuel pumping and control system 10. Controller 26 then regulates the speed of motor 18 based on those signals. The speed of motor 18 controls the amount and speed of fuel pumping in pump assembly 20. Pump assembly 20 receives fuel from a fuel tank (not shown) through inlet 22 and pumps fuel through outlet 24. Inlet 22 can be located on housing 12 at wet compartment 14 to feed directly into pump assembly 20. Fuel outlet 24 can connect to a fuel manifold of an engine (not shown) for connecting to a combustor for powering the engine.

Past fuel pumping systems and controls were not integrated and included separate housings for wet components (the motor and pump assembly) and dry components (the controller). This resulted in a need for wires and connectors to run between the motor and pump assembly and the controller to facilitate control of the pumping process. The connectors made the system quite large compared to the sometimes very small components used, for example in missile fuel systems, the motor, pump and controller are very small. The wires and connectors connecting the wet and dry components were also vulnerable to being dislodged or disconnected from components, thereby making the system inoperable. Additionally, past systems generally included a fuel line running from a fuel tank to deliver fuel to the pumping system in addition to the fuel delivery line to the manifold.

Fuel pumping and control system 10 integrates wet components (motor 18 and pump assembly 16) and dry components (controller 26) into a single housing 12 with wet section 14 and dry section 16. This integration makes fuel and control system 10 more reliable than past systems by eliminating the need for vulnerable wires and connectors between wet components and dry components at different locations. Additionally, it results in an overall smaller system by integrating motor 18, pump assembly 16 and controller 26 in a single housing, resulting in savings of weight and space. Within fuel pumping and control system 10, housing 12 can also be mounted directly onto a fuel tank (not shown) with bolts through holes 30. This provides built-in cooling for electronics in dry compartment 16 as the ambient temperature of the fuel tank is much cooler than the temperature of the electronics. This also eliminates fuel lines of past systems, resulting in more savings in weight and space within the overall system. A reduction in volume of fuel pumping and control system 10 over past systems also can make for an easier installation over past systems.

While the system has been shown with specific dimensions and specific placement of wet components and dry components, these are for example purposes only and may be varied. Additionally, fuel pumping and control system 10 could include other components, such as a shut-off valve depending on system requirements.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. An integrated fuel pump and control system, the system comprising:
a pump assembly with an inlet and an outlet;
a motor connected to the pump assembly to provide power to the pump assembly;
a controller to regulate the motor; and
a housing to contain the pump assembly, the motor and the controller.

2. The system of claim 1, wherein the housing comprises:
a dry compartment to contain the controller; and
a wet compartment to contain the pump assembly.

3. The system of claim 2, wherein the wet compartment also contains the motor.

4. The system of claim 1, wherein the motor is a brushless motor.

5. The system of claim 1, wherein the controller is connected to a computer that sends a signal to the controller for controlling the motor.

6. The system of claim 1, wherein the motor is connected to the pump such that the speed of the pump varies based on the speed of the motor.

7. The fuel pump and control system of claim 1, wherein the motor controls the speed and amount of fuel pumped out of the fuel outlet of the pump assembly by controlling the speed of the pump.

8. The fuel pump and control system of claim 1, wherein the housing connects to a fuel tank.

9. A system for pumping fuel to an engine, the system comprising:
a housing with a wet compartment and a dry compartment;
a pumping system in the wet compartment with a fuel inlet and a fuel outlet; and
a controller in the dry compartment to regulate the pumping system.

10. The system of claim 9, wherein the pumping system comprises:
a pump to transfer the fuel; and
a motor to provide power to regulate the pumping of the fuel and connected to the pump and to the controller.

11. The system of claim 9, wherein the controller and motor control the speed and amount of fuel that is pumped through the fuel outlet.

12. The system of claim 9, wherein the housing is one integral component with a flat base section and a cover section which extends in the depth dimension to contain the pumping system and the controller.

13. The system of claim 9, wherein the housing dimensions are no greater than about 6 inches (about 15.24 cm) wide and about 4 inches (about 10.16 cm) in length.

14. The system of claim 9, wherein the housing depth dimension of the wet compartment is no greater than about 1.875 inches (about 4.7625 cm).

15. The system of claim 9, wherein the housing depth dimension of the dry compartment is no greater than about 0.625 inches (about 1.5875 cm).

16. The system of claim 9, wherein the controller is connected to a computer that sends a signal to the controller for controlling the motor.

17. A method of forming an integrated fuel pump and control system, the method comprising:
providing a housing with a wet portion and a dry portion;
placing a pump assembly in the wet portion for transferring fuel through an outlet;
placing a motor in the wet portion for providing power for the pump assembly; and
placing a controller in the dry portion for regulating the motor.

18. The method of claim 17, wherein the step of placing a motor in the wet portion comprises placing a brushless motor in the wet portion and connecting it to the pump assembly.

19. The method of claim 17, wherein the step of placing a controller in the dry portion further comprises:
connecting the controller to the motor.

20. The method of claim 19, and further comprising:
connecting the controller to a computer sends a signal to the controller for controlling the motor.
